(19) United States
(12) Patent Application Publication
(10) Pub. No.: US 2026/0262236 A1
(43) Pub. Date: Sep. 3, 2026

(54) SEMICONDUCTOR DEVICE

(71) Applicant: FUJI ELECTRIC CO., LTD., Kanagawa (JP)

(72) Inventors: Kazuki KAMIMURA, Matsumoto-city (JP); Tatsuhiko FUJIHIRA, Matsumoto-city (JP); Tatsuya NAITO, Matsumoto-city (JP); Masahiro SASAKI, Azumino-city (JP); Norihiro KOMIYAMA, Matsumoto-city (JP)

(21) Appl. No.: 19/654,467

(22) Filed: Apr. 22, 2026

Related U.S. Application Data
(63) Continuation of application No. PCT/JP2025/009206, filed on Mar. 11, 2025.

(30) Foreign Application Priority Data
Apr. 25, 2024 (JP) 2024-071639

(51) Int. Cl. H10D 12/00; H10D 1/47; H10D 8/00; H10D 64/27; H10D 84/00; H10D 84/80; H10D 62/10

(52) U.S. Cl. CPC H10D 12/481; H10D 1/47; H10D 8/422; H10D 64/519; H10D 84/161; H10D 84/811; H10D 62/124

(57) ABSTRACT

A semiconductor device comprising a semiconductor substrate having an upper surface, wherein the semiconductor substrate has a main transistor portion having a main gate trench portion including a main gate conductive portion, a sense transistor portion having a sense gate trench portion including a sense gate conductive portion, a gate pad provided above the upper surface of the semiconductor substrate, a main gate runner provided above the upper surface of the semiconductor substrate and extending from the gate pad to the main gate conductive portion, a sense gate runner disposed along the sense transistor portion, and a gate runner connection portion connecting the main gate runner and the sense gate runner, and a resistor portion is provided in the gate runner connection portion.

The contents of the following patent application(s) are incorporated herein by reference:

NO. 2024-071639 filed in JP on April 25, 2024

NO. PCT/JP2025/009206 filed in WO on March 11, 2025.

### BACKGROUND

### 1. TECHNICAL FIELD

The present invention relates to a semiconductor device.

### 2. RELATED ART

Conventionally, an overcurrent protection device for a transistor, in which a gate resistor is connected to a current detection transistor, is known (see, for example, Patent Document 1). In addition, a semiconductor device in which a diode and a resistor runner are arranged in a gate runner is known (see, for example, Patent Document 2).

### Related Art Documents

### Patent Documents

Patent Document 1: Japanese Unexamined Patent Application Publication No.7-146722

Patent Document 2: Japanese Patent No. 6510310

### BRIEF DESCRIPTION OF THE DRAWINGS

FIG. 1 is a diagram illustrating an equivalent circuit of a semiconductor device 100 according to one embodiment of the present invention.

FIG. 2 illustrates a top view of one example of the semiconductor device 100 according to one embodiment of the present invention.

FIG. 3A illustrates an enlarged view of a region A in FIG. 2.

FIG. 3B is an enlarged view of the region A in FIG. 2.

FIG. 3C is an enlarged view of the region A in FIG. 2.

FIG. 4 is a diagram illustrating one example of a B-B' cross section in FIG. 3A.

FIG. 5A is a diagram illustrating simulation results of the gate voltage.

FIG. 5B is a diagram illustrating simulation results of the gate voltage.

FIG. 5C is a diagram illustrating simulation results of the gate voltage.

FIG. 6 is a diagram illustrating another example of the B-B' cross section in FIG. 3A.

FIG. 7 is a diagram illustrating another example of the B-B' cross section in FIG. 3A.

FIG. 8 is a diagram illustrating another example of the B-B' cross section in FIG. 3A.

FIG. 9 is a diagram illustrating one example of a configuration of the gate runner connection portion 50 in a top view.

FIG. 10 is a diagram illustrating one example of the D-D' cross section of FIG. 9.

FIG. 11 is a diagram illustrating one example of the C-C' cross section of FIG. 3A.

FIG. 12 is a diagram illustrating one example of the cross section A-A’ in FIG. 2.

FIG. 13 is a diagram illustrating another example of the region A in FIG. 2.

FIG. 14 is a diagram illustrating another example of the region A in FIG. 2.

FIG. 15 is a diagram illustrating another example of the cross section A-A’ in FIG. 2.

FIG. 16 is a diagram illustrating another example of the B-B' cross section in FIG. 3A.

### DESCRIPTION OF EXEMPLARY EMBODIMENTS

The present invention will be described below through embodiments of the invention, but the following embodiments do not limit the invention according to the claims. In addition, not all of the combinations of features described in the embodiments are essential to the solving means of the invention. In the present specification, the same parts in each figure are denoted by the same signs and numerals, and the descriptions thereof may be omitted. In addition, for convenience of description, some configurations may not be illustrated.

As used herein, one side in a direction parallel to a depth direction of a semiconductor substrate is referred to as “upper” and the other side is referred to as “lower”. One surface of two main surfaces of a substrate, a layer or other member is referred to as an upper surface, and the other surface is referred to as a lower surface. “Upper” and “lower” directions are not limited to a direction of gravity, or a direction in which a semiconductor device is mounted.

In the present specification, technical matters may be described using an orthogonal coordinate system of an X axis, a Y axis, and a Z axis. The orthogonal coordinate system merely specifies relative positions of components, and does not limit a particular direction. For example, the Z axis direction is not limited to illustrating a height direction with respect to the ground. Note that a +Z axis direction and a -Z axis direction are directions opposite to each other. When the Z axis direction is described without describing the signs, it means that the direction is parallel to the +Z axis and the -Z axis.

In the present specification, orthogonal axes parallel to the upper surface and the lower surface of the semiconductor substrate are referred to as the X axis and the Y axis, respectively. In addition, an axis perpendicular to the upper surface and the lower surface of the semiconductor substrate is referred to as the Z axis. In the present specification, the direction of the Z axis may be referred to as a depth direction. In addition, in the present specification, a direction parallel to the upper surface and the lower surface of the semiconductor substrate may be referred to as a horizontal direction, including the X axis and the Y axis.

When a term such as “same” or “equal” is used herein, it may encompass a case where an error due to a variation in manufacturing or the like is included. The error is, for example, within 10%. In addition, in the present specification, the terms "parallel" or "perpendicular" may include an error of within 5°.

In the present specification, a conductivity type of a doping region doped with impurities is described as a P type or an N type. In the present specification, the impurities may particularly mean either donors of the N type or acceptors of the P type and may be described as dopants. In the present specification, doping means introducing the donors or the acceptors into the semiconductor substrate and turning it into a semiconductor presenting a conductivity type of the N type, or a semiconductor presenting a conductivity type of the P type. In the present specification, the doping concentration of the N type region may be referred to as the donor concentration, and the doping concentration of the P type region may be referred to as the acceptor concentration.

In the present specification, a description of a P+ type or an N+ type means a higher doping concentration than that of the P type or the N type, and a description of a P- type or an N- type means a lower doping concentration than that of the P type or the N type. In the present specification, a unit system is the SI base unit system unless otherwise noted.

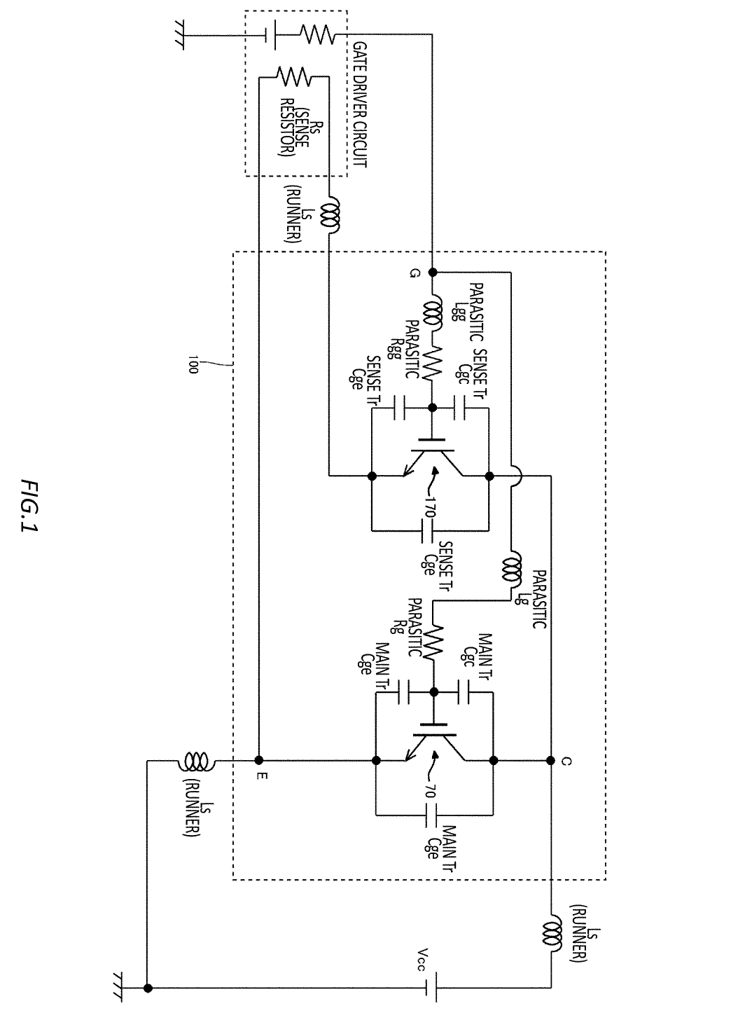

FIG. 1 is a diagram illustrating an equivalent circuit of a semiconductor device 100 according to one embodiment of the present invention. The semiconductor device 100 includes the main transistor portion 70 and the sense transistor portion 170. The sense transistor portion 170 has a structure similar to that of the main transistor portion 70, and measures a current flowing through the main transistor portion 70. The main transistor portion 70 and the sense transistor portion 170 may be formed in the same chip. The main transistor portion 70 and the sense transistor portion 170 of this example are IGBTs, but the main transistor portion 70 and the sense transistor portion 170 may be MOSFETs.

The collector electrode of the main transistor portion 70 and the collector electrode of the sense transistor portion 170 are connected to each other, and are connected to the common collector terminal (C). The gate of the main transistor portion 70 and the gate of the sense transistor portion 170 are connected to the common gate driver circuit via gate terminals (G). The gate runner of the main transistor portion 70 and the sense transistor portion 170 has parasitic resistance components Rg and Rgg and parasitic inductance components Lg and Lgg. respectively.

The emitter electrode of the main transistor portion 70 (which may be referred to as the main emitter electrode) and the emitter electrode of the sense transistor portion 170 (which may be referred to as the sense emitter electrode) are electrically separated inside the semiconductor device 100. The main emitter electrode of the main transistor portion 70 is connected to the emitter terminal (E), and is supplied with the emitter potential. The sense emitter electrode of the sense transistor portion 170 is connected to the emitter terminal via the sense resistor Rs. The voltage Vcc is applied between the collector terminal and the emitter terminal from an external power supply.

When the semiconductor device 100 operates, the predetermined current flows through the main transistor portion 70, and the current corresponding to the current value of the main transistor portion 70 flows through the sense transistor portion 170. The current value flowing through the sense transistor portion 170 is measured based on the voltage drop across the sense resistor Rs at that time. The current value of the main transistor portion 70 is estimated based on the measurement results in the sense transistor portion 170. This makes it possible to detect an overcurrent in the main transistor portion 70 and to stop the apparatus. The inductance component of the wires, wiring, and the like is represented as Ls.

The main transistor portion 70 has the gate-emitter capacitance Cge, the gate-collector capacitance Cgc, and the collector-emitter capacitance Cce. Similarly, the sense transistor portion 170 also has the gate-emitter capacitance Cge, the gate-collector capacitance Cgc, and the collector-emitter capacitance Cce. Since the main transistor portion 70 and the sense transistor portion 170 are connected in parallel, a feedback loop is formed along a path of the gate terminal, the sense transistor portion 170, the emitter terminal, the main transistor portion 70, and the gate terminal. Therefore, voltage oscillation may occur in the feedback loop. In this specification, the oscillation may be referred to as parallel oscillation.

The gate-emitter capacitance Cge of the sense transistor portion 170 is significantly smaller than the gate-emitter capacitance Cge of the main transistor portion 70. Therefore, when parallel oscillation occurs, the gate signal of the sense transistor portion 170 is easily affected, and the gate voltage of the sense transistor portion 170 may oscillate. In particular, this tendency becomes remarkable as the performance of the semiconductor device 100 improves. When the gate voltage of the sense transistor portion 170 oscillates, malfunction may occur in the main transistor portion 70 or the sense transistor portion 170, and may cause a reduction in the short-circuit withstand capability. Therefore, it is preferable to suppress parallel oscillation. In an embodiment of the present invention, by providing a resistor in the gate runner of the sense transistor portion 170, the resistor is provided in the feedback loop to suppress parallel oscillation.

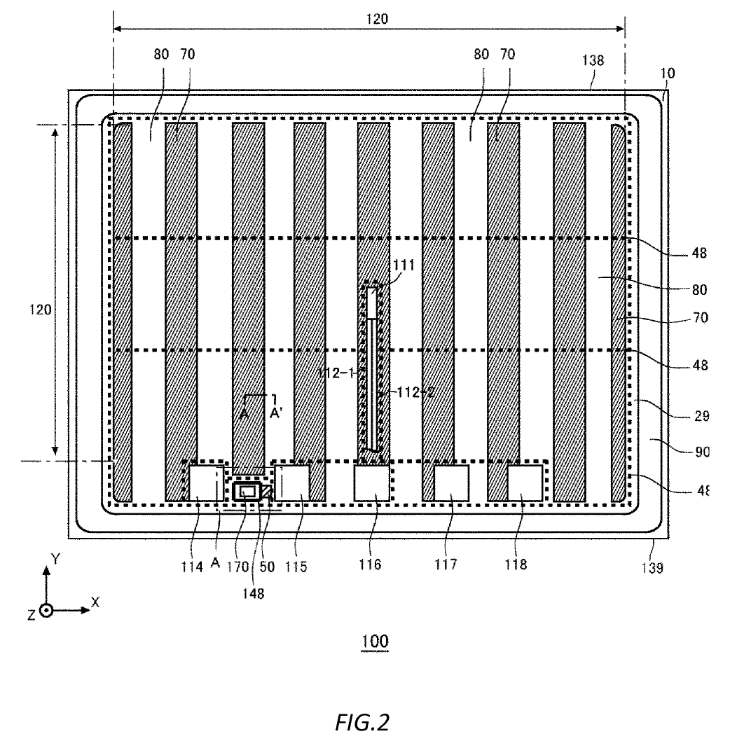

FIG. 2 illustrates a top view of one example of the semiconductor device 100 according to one embodiment of the present invention. FIG. 2 shows a position obtained by projecting a position of each member onto an upper surface of a semiconductor substrate 10. In FIG. 2, only some members of the semiconductor device 100 are shown, and some members thereof are omitted.

The semiconductor device 100 includes the semiconductor substrate 10. The semiconductor substrate 10 is a substrate formed of a semiconductor material. As one example, the semiconductor substrate 10 is a silicon substrate. Ends of an outer perimeter of the semiconductor substrate 10 when viewed in the top view are referred herein to as outer perimeter ends 138. The phrase "when viewed in the top view" refers to a case where an object is seen in parallel with the Z axis from the upper surface side of the semiconductor substrate 10. In addition, any one end side in the outer perimeter ends 138 of the semiconductor substrate 10 when viewed in the top view is referred to as a first end side 139. A direction parallel to the first end side 139 when viewed in the top view is referred to as an X axis direction, and a direction perpendicular to the first end side 139 is referred to as a Y axis direction.

The semiconductor substrate 10 is provided with an active portion 120. The active portion 120 is a region through which a main current flows in the depth direction between the upper surface and the lower surface of the semiconductor substrate 10 when the semiconductor device 100 operates. The active portion 120 may be a region in which the main transistor portion 70 is formed. The main emitter electrode is provided above the active portion 120, but is omitted in FIG. 2.

In the active portion 120, at least one of the main transistor portion 70 including a transistor element such as an IGBT or a diode portion 80 including a diode element such as a freewheeling diode (FWD) is provided. In the example of FIG. 2, the main transistor portion 70 and the diode portion 80 are alternately arranged along the X axis direction. Note that the diode portion 80 does not have to be provided.

The main transistor portion 70 and the diode portion 80 of this example each have the longitudinal dimension in the Y axis direction. In other words, the length of the main transistor portions 70 in the Y axis direction is greater than the width in the X axis direction. Similarly, the length of the diode portions 80 in the Y axis direction is greater than the width in the X axis direction. The longitudinal direction of the main transistor portion 70 and the diode portion 80 and the longitudinal direction of each trench portion described later may be the same.

Each of the diode portions 80 includes a cathode region of an N+ type in a region in contact with the lower surface of the semiconductor substrate 10. In the present specification, a region where the cathode region is provided is referred to as the diode portion 80. In other words, the diode portion 80 is a region that overlaps with the cathode region in the top view. On the lower surface of the semiconductor substrate 10, a collector region of a P+ type may be provided in a region other than the cathode region. In the present specification, the diode portion 80 may also include a region extended from the diode portion 80 to an active well region described later in the Y axis direction. The collector region is provided on a lower surface of the extended region.

Above the upper surface of the semiconductor substrate 10, a plurality of pad portions are provided. In the example of FIG. 2, above the upper surface of the semiconductor substrate 10, a sense pad 114, an auxiliary emitter pad 115, a gate pad 116, a cathode pad 117, and an anode pad 118 are provided.

The sense pad 114 is connected to the sense transistor portion 170. The sense transistor portion 170 has the same structure as the main transistor portion 70, and has a smaller area in a top view (corresponding to the area of the channel) than the main transistor portion 70. By detecting the current flowing through the sense transistor portion 170, a current flowing through the entirety of the semiconductor device 100 can be estimated. When wiring an output from the sense transistor portion 170 to the main emitter electrode, wiring may be extended from the sense pad 114.

The auxiliary emitter pad 115 is connected to the main emitter electrode disposed above the upper surface of the semiconductor substrate 10. Wiring extended from the sense pad 114 may be connected to the main emitter electrode by wire bonding at the auxiliary emitter pad 115 in order to be at the same potential as the main emitter electrode.

A gate signal is sent to the gate pad 116 from the gate driver circuit. The gate pad 116 is connected, via the gate runner, to the gates of the main transistor portion 70 and the sense transistor portion 170.

The cathode pad 117 and the anode pad 118 are connected to the temperature sense portion 111 via a temperature sense runner 112. The temperature sense portion 111 measures the temperature of the semiconductor device 100. The temperature sense portion 111 is, as one example, the diode for temperature measurement. The temperature sense runner 112 extends from the temperature sense portion 111 to a region between the active portion 120 and the outer perimeter end 138 on the upper surface of the semiconductor substrate 10, and is connected to the cathode pad 117 and the anode pad 118. The temperature sense runner 112 may be polysilicon. It should be noted that a number and types of pad portions provided to the semiconductor substrate 10 are not limited to those in the example shown in FIG. 2.

Each pad portion is formed of a metal material such as aluminum. The plurality of pad portions may be arranged in a predetermined direction between the active portion 120 and the first end side 139 on the upper surface of the semiconductor substrate 10. The plurality of pad portions of this example are arranged in the X axis direction, and are disposed so as to be sandwiched between the active portion 120 and the first end side 139 in the Y axis direction. The plurality of pad portions of this example are provided above the active main well region 29 described later.

In the arrangement direction of the plurality of pad portions, the sense transistor portion 170 may be provided between any two pad portions. The sense transistor portion 170 of this example is disposed between the sense pad 114 and the auxiliary emitter pad 115 in the X axis direction.

As described later, the sense transistor portion 170 has a sense gate trench portion with a trench structure. The sense gate trench portion has a sense gate conductive portion to which a gate voltage is applied. As will be described later, the main transistor portion 70 also has the main gate trench portion with a trench structure. The main gate trench portion has the main gate conductive portion to which a gate voltage is applied.

The semiconductor substrate 10 has the main gate runner 48 and the sense gate runner 148. The main gate runner 48 is provided on an upper surface of the semiconductor substrate 10 and surrounds the active portion 120 and at least one of the plurality of pad portions. It is also provided so as to cross the active portion 120. The main gate runner 48 is connected to the main gate conductive portion of the main transistor portion 70. That is, the main gate runner 48 extends from the gate pad 116 to the main gate conductive portion.

The main gate runner 48 is the runner that transmits the gate signal to the main gate conductive portion. The main gate runner 48 may be the runner through which the charging current for charging the main gate conductive portion flows. The main gate runner 48 may be the gate runner other than the sense gate runner 148 described later. FIG. 2 indicates the main gate runner 48 with dotted lines.

The sense gate runner 148 is provided above the upper surface of the semiconductor substrate 10 and is disposed along the sense transistor portion 170. The sense gate runner 148 of this example surrounds the sense transistor portion 170. The sense gate runner bis connected to the sense gate conductive portion of the sense transistor portion 170. Being disposed along the sense transistor portion 170 may refer to being disposed in parallel with any side of the sense transistor portion 170. The distance between the sense gate runner 148 and the sense transistor portion 170 may be smaller than the distance between the sense transistor portion 170 and the sense pad 114. For example, when the sense transistor portion 170 is rectangular, the sense gate runner 148 may be disposed in parallel with two or more sides of the sense transistor portion 170, and may be disposed in parallel with three or more sides. When there are a plurality of gate runners disposed in parallel with any side of the sense transistor portion 170, the sense gate runner 148 may refer to the gate runner closest to the sense transistor portion 170.

The sense gate runner 148 is the runner for transmitting the gate signal to the sense gate conductive portion. The sense gate runner 148 may be, among the runners through which a charging current for charging the sense gate conductive portion flows, the runner disposed along an outer shape of the sense transistor portion 170. The sense gate runner 148 does not have to include the runner through which a charging current for charging the main gate conductive portion flows.

FIG. 2 indicates the sense gate runner 148 with a thick solid line. The sense gate runner 148 of this example is arranged in a closed-loop shape surrounding the sense transistor portion 170. At least a part of the main gate runner 48 and the sense gate runner 148 may have a stacked structure of metal and polysilicon. An insulating film may be provided between the metal runner and the polysilicon runner. The metal runner and the polysilicon runner may be electrically connected via a contact hole provided on the insulating film. The main gate runner 48 and the sense gate runner 148 are insulated from the upper surface of the semiconductor substrate 10 by an interlayer insulating film.

The semiconductor substrate 10 has the gate runner connection portion 50 connecting the main gate runner 48 to the sense gate runner 148. The gate runner connection portion 50 of this example is arranged between the sense transistor portion 170 and the auxiliary emitter pad 115. The gate runner connection portion 50 is the runner that transmits the gate signal to the sense gate conductive portion, and is the runner through which a charging current for charging the sense gate conductive portion flows. That is, the sense gate runner 148 is provided between the gate terminal (G) in FIG. 1 and the gate of the sense transistor portion 170. The gate runner connection portion 50 may be the runner through which a charging current for charging the main gate conductive portion does not flow.

The semiconductor substrate 10 includes the active main well region 29 formed so as to surround the active portion 120 in a top view. The active main well region 29 surrounds the main transistor portion 70 and the diode portion 80 in a top view. The active main well region 29 is a region of a second conductivity type provided from the upper surface to the inside of the semiconductor substrate 10. The active main well region 29 may surround the active portion 120 along the main gate runner 48. The active main well region 29 is also provided around the pad portion, but illustration around the pad portion is omitted in FIG. 2.

An edge termination structure portion 90 is provided between the active well region and the outer perimeter end 138 of the semiconductor substrate 10 at the upper surface of the semiconductor substrate 10. The edge termination structure portion 90 may be circularly arranged so as to surround the active well region at the upper surface of the semiconductor substrate 10. The edge termination structure portion 90 of this example is arranged along the outer perimeter ends 138 of the semiconductor substrate 10. The edge termination structure portion 90 reduces an electric field strength on the upper surface side of the semiconductor substrate 10. The edge termination structure portion 90 includes, for example, a guard ring, a field plate, a RESURF and a combination structure of them.

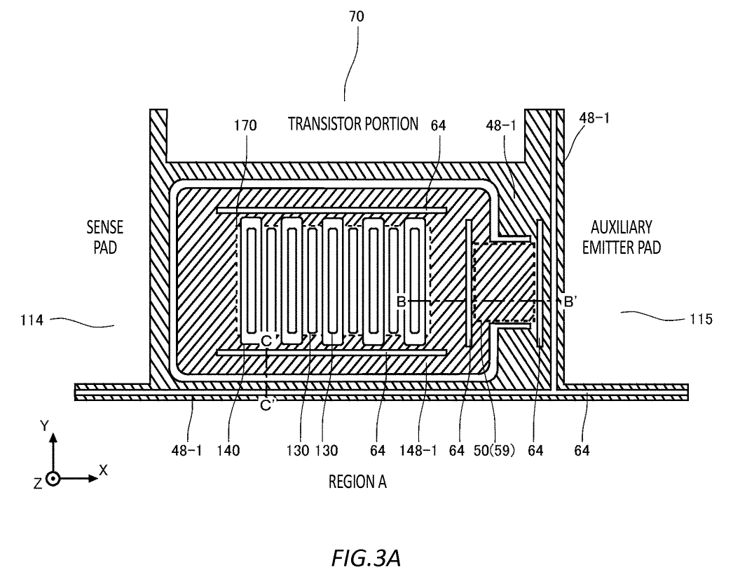

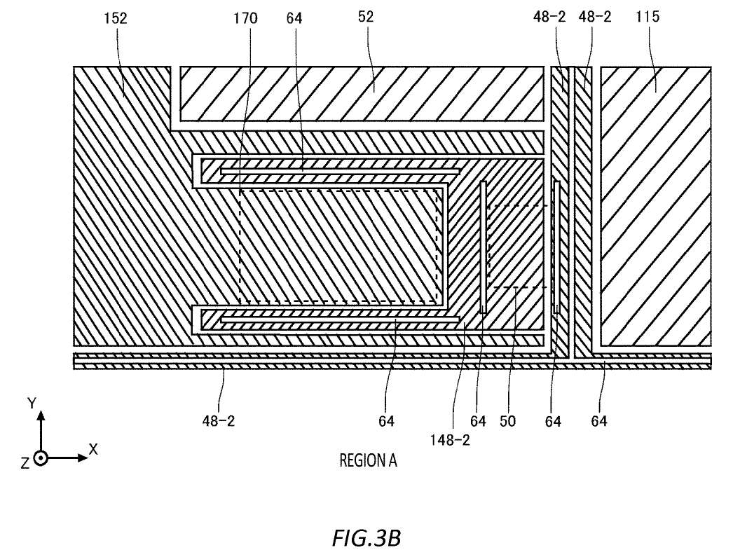

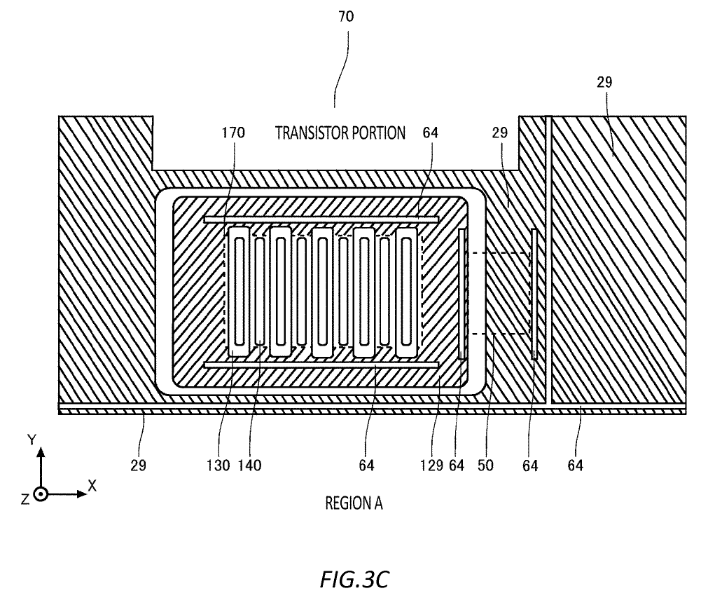

FIG. 3A illustrates an enlarged view of a region A in FIG. 2. The region A is the region including the sense transistor portion 170, the gate runner connection portion 50, and a peripheral region thereof. The sense transistor portion 170 of this example faces the main transistor portion 70 in the Y axis direction. As one example, the length of the sense transistor portion 170 in the Y axis direction is 300 μm or more and 400 μm or less.

The sense transistor portion 170 includes the sense gate trench portion 140 and the sense dummy trench portion 130. The sense gate trench portion 140 and the sense dummy trench portion 130 of this example extend in the Y axis direction.

The main gate runner 48 and the sense gate runner 148 of this example have the stacked structure of metal and polysilicon. The insulating film may be provided between the metal runner and the polysilicon runner. The metal runner and the polysilicon runner may be electrically connected via the contact hole provided on the insulating film. In this specification, the polysilicon of the main gate runner 48 is defined as the second polysilicon layer 48-1. Also, the polysilicon of the sense gate runner 148 is defined as the third polysilicon layer 148-1. In FIG. 3A, hatching is applied to the second polysilicon layer 48-1 and the third polysilicon layer 148-1. However, at least a part of the main gate runner 48 and the sense gate runner 148 may have a stacked structure, and the entirety thereof need not have a stacked structure.

The second polysilicon layer 48-1 is provided, in a top view, along the main transistor portion 70, the sense pad 114, and the auxiliary emitter pad 115. Also, the main gate runner 48 is provided so as to surround the sense transistor portion 170 and the sense gate runner 148. The interlayer insulating film (not illustrated) is formed between the second polysilicon layer 48-1 and the metal of the main gate runner 48. The contact hole 64 is formed in the interlayer insulating film, and the metal of the main gate runner 48 and the second polysilicon layer 48-1 are connected via the contact hole 64. However, the contact hole 64 shown in FIG. 3A may actually include a plurality of through holes.

The third polysilicon layer 148-1 is provided, in a top view, in a closed-loop shape surrounding the sense transistor portion 170. The interlayer insulating film (not illustrated) is also formed between the third polysilicon layer 148-1 and the metal of the sense gate runner 148. The contact hole 64 is formed in the interlayer insulating film, and the metal of the sense gate runner 148 and the third polysilicon layer 148-1 are connected via the contact hole 64.

The third polysilicon layer 148-1 and the sense gate trench portion 140 have an overlapping portion in a top view, and in the portion, the third polysilicon layer 148-1 and the sense gate conductive portion of the sense gate trench portion 140 are connected. The third polysilicon layer 148-1 does not have to be connected to the sense dummy conductive portion of the sense dummy trench portion 130. The sense dummy conductive portion of the sense dummy trench portion 130 may be connected to the sense emitter electrode.

The gate runner connection portion 50 connects the third polysilicon layer 148-1 and the second polysilicon layer 48-1. The gate signal is transmitted from the main gate runner 48 to the sense gate runner 148 via the gate runner connection portion 50. A resistor portion 59 is provided in the gate runner connection portion 50. The resistor portion 59 is a portion having a higher resistance value per unit length in a direction in which current flows through the resistor portion 59 than the main gate runner 48 or the sense gate runner 148 connected to the resistor portion 59. In the resistor portion 59, current flows in the connection direction (for example, the X axis direction) along which the main gate runner 48 and the sense gate runner 148 are connected. The resistance value per unit length of the resistor portion 59 in the connection direction is higher than the resistance value per unit length in the connection direction of the portion of the main gate runner 48 that is connected to the resistor portion 59, and is higher than the resistance value per unit length in the connection direction of the portion of the sense gate runner 148 that is connected to the resistor portion 59. The resistance value per unit length of the resistor portion 59 may be two times or more, five times or more, or ten times or more the resistance value per unit length of the main gate runner 48 or the sense gate runner 148. If the resistance value is higher in a range in which the gate runner connection portion 50 is provided than in the case where the runner similar to the main gate runner 48 or the sense gate runner 148 is extended as the gate runner connection portion 50, the gate runner connection portion 50 may be regarded as being provided with the resistor portion 59. The resistor portion 59 is formed of polysilicon as one example. The main gate runner 48 and the sense gate runner 148 in portions connected to the resistor portion 59 are, as one example, stacked runners of polysilicon and metal. In FIG. 3A, hatching is also applied to the polysilicon of the resistor portion 59.

The gate runner connection portion 50 having the resistor portion 59 can suppress the above-described parallel oscillation. Therefore, oscillation of the gate voltage of the sense transistor portion 170 can be suppressed. The structure of the gate runner connection portion 50 will be described later. The third polysilicon layer 148-1 and the second polysilicon layer 48-1 are not connected at locations other than the gate runner connection portion 50. As one example, the length of the gate runner connection portion 50 in the Y axis direction is 100 μm or more and 300 μm or less, and the length in the X axis direction is 100 μm or more and 150 μm or less.

The contact hole 64 that connects the main gate runner 48 and the gate runner connection portion 50 is provided on the positive X axis side of the gate runner connection portion 50 of this example. Also, the contact hole 64 that connects the sense gate runner 148 and the gate runner connection portion 50 is provided on the negative X axis side of the gate runner connection portion 50. In this example, the contact hole 64 on the negative X axis side of the gate runner connection portion 50, the contact hole 64 provided on the positive Y axis side of the sense transistor portion 170, and the contact hole 64 provided on the negative Y axis side are separated from each other, but these may be provided continuously so as to surround the sense transistor portion 170 in a U-shape.

The sense gate trench portion 140 of this example extends in the extending direction (Y axis direction). The sense gate runner 148 of this example is connected to both ends of the sense gate trench portion 140 in the extending direction, respectively. The gate runner connection portion 50 of this example is provided at a position overlapping the sense transistor portion 170 in the direction (X axis direction) perpendicular to the extending direction in a top view. Therefore, the difference in runner length of the sense gate runner 148 from the gate runner connection portion 50 to a connection portion with each sense gate trench portion 140 is small. Thus, gate delay (variation in switching speed) of the sense gate trench portion 140 can be suppressed. The gate runner connection portion 50 may be provided at a position overlapping the center in the extending direction of the sense transistor portion 170 in a direction perpendicular to the extending direction.

The sense transistor portion 170 of this example is disposed adjacent to the sense pad 114 in the X axis direction. The gate runner connection portion 50 of this example is provided on a side opposite to the sense pad 114 with reference to the sense transistor portion 170. Such an arrangement can also suppress the gate delay (variation in switching speed) of the sense gate trench portion 140. The sense pad 114 and the gate runner connection portion 50 may be arranged so as to sandwich the sense transistor portion 170 in the direction perpendicular to the extending direction in a top view.

FIG. 3B is an enlarged view of the region A in FIG. 2. FIG. 3B illustrates metal of the main gate runner 48 (which may be referred to as the second metal layer 48-2), metal of the sense gate runner 148 (which may be referred to as the third metal layer 148-2), the main emitter electrode 52, the sense emitter electrode 152, and the auxiliary emitter pad 115.

As described above, the second polysilicon layer 48-1 and the second metal layer 48-2 are stacked, and are connected via the contact hole 64 provided to extend along a direction in which current flows. The same is true for the third polysilicon layer 148-1 and the third metal layer 148-2 are similarly configured.

The third metal layer 148-2 is provided along three sides of the sense transistor portion 170. The sense emitter electrode 152 is provided on the other one side of the sense transistor portion 170. Therefore, the third metal layer 148-2 does not surround the sense transistor portion 170.

The sense emitter electrode 152 extends in the negative X axis direction from above the sense transistor portion 170 to the sense pad 114. Therefore, current flowing through the sense transistor portion 170 is output to the sense pad 114. The direction in which the sense emitter electrode 152 extends from the sense transistor portion 170 to the sense pad 114 may be perpendicular to the extending direction (Y axis direction) of the sense gate trench portion 140 (see FIG. 3A). In addition, the sense emitter electrode 152 of this example also extends, in the Y axis direction, between the main emitter electrode 52 and the third metal layer 148-2 and between the third metal layer 148-2 and the second metal layer 48-2.

FIG. 3C illustrates an enlarged view of a region A in FIG. 2. In FIG. 3C, in addition to the sense transistor portion 170 and the gate runner connection portion 50, the main well region 29 and the sense well region 129 are illustrated.

The main well region 29 surrounds the active portion 120. FIG. 3C illustrates the band portion of the main well region 29 surrounding the active portion 120. The main gate runner 48, the sense pad 114, and the auxiliary emitter pad 115 are arranged to overlap the main well region 29 in a top view. In the main transistor portion 70, an end portion of the main gate trench portion extending in the Y axis direction may overlap the main well region 29.

The sense well region 129 surrounds the sense transistor portion 170 in a top view. The sense well region 129 is the second conductivity type region formed from the upper surface to the inside of the semiconductor substrate 10. The doping concentrations of the main well region 29 and the sense well region 129 may be the same or may be different. By providing the sense well region 129, holes that have migrated around from the main transistor portion 70 to the sense transistor portion 170 can be extracted, and accumulation of holes in the sense transistor portion 170 can be suppressed. At least a part of the sense well region 129 may face the main transistor portion 70.

The sense gate runner 148 is arranged to overlap the sense well region 129 in a top view. An end portion of the sense gate trench portion 140 may overlap the sense well region 129. The sense well region 129 and the main well region 29 are separated. The sense well region 129 of this example is surrounded by the main well region 29. In addition, the gate runner connection portion 50 may be provided from a position overlapping the main well region 29 to a position overlapping the sense well region 129 in a top view.

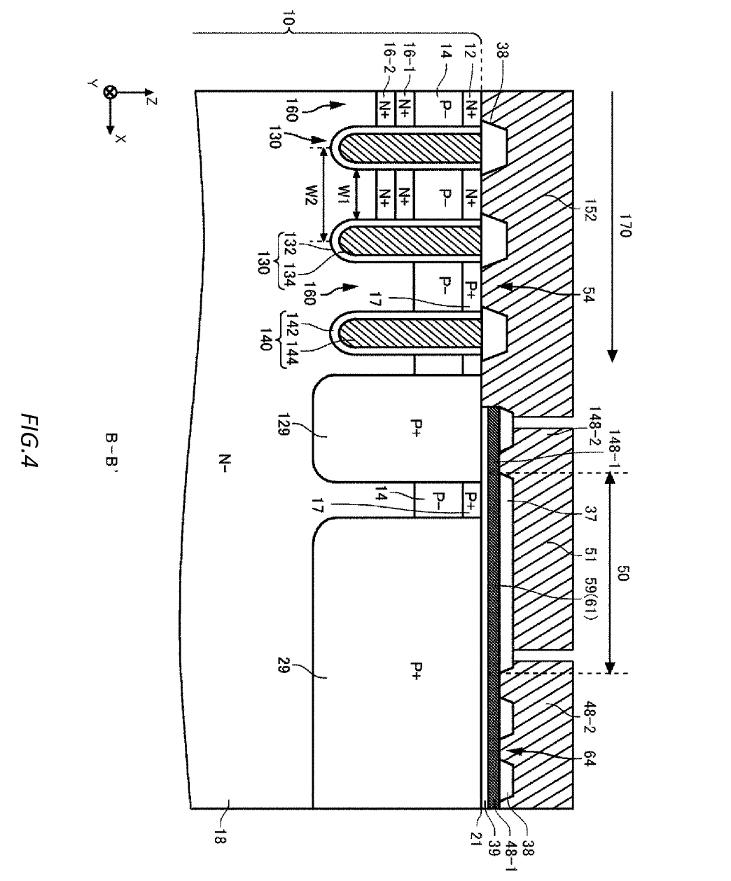

FIG. 4 is a diagram illustrating one example of the B-B' cross section in FIG. 3A. The B-B' cross section is an XZ cross section passing through the emitter region 12, the sense well region 129, and the active main well region 29 of the sense transistor portion 170. In the B-B' cross section, the semiconductor device 100 includes the semiconductor substrate 10, the interlayer insulating film 38, the sense emitter electrode 152, the sense gate runner 148, the main gate runner 48, and the gate runner connection portion 50. In FIG. 4, only a configuration on the upper surface side of the semiconductor substrate 10 is illustrated.

The semiconductor substrate 10 has the upper surface 21. The interlayer insulating film 38 is provided on the upper surface 21 of the semiconductor substrate 10. The interlayer insulating film 38 is a film including at least one layer of an insulating film such as silicate glass to which impurities such as boron or phosphorous are added, a thermal oxide film, and other insulating films. The interlayer insulating film 38 has a contact hole 54 provided therein.

The sense emitter electrode 152 is provided above the interlayer insulating film 38 in the sense transistor portion 170. The sense emitter electrode 152 is in contact with the upper surface 21 of the semiconductor substrate 10 through the contact hole 54 of the interlayer insulating film 38. The sense emitter electrode 152 is formed of a metal material such as aluminum.

The sense transistor portion 170 has the drift region 18 of a first conductivity type and the base region 14 of a second conductivity type provided between the drift region 18 and the upper surface 21 of the semiconductor substrate 10. The drift region 18 of this example is of an N- type, and the base region 14 is of a P- type.

The sense transistor portion 170 has a sense gate trench portion 140 and a sense dummy trench portion 130 provided from the upper surface 21 of the semiconductor substrate 10 toward the inside. The sense gate trench portion 140 and the sense dummy trench portion 130 of this example are arranged along the X axis direction and have a longitudinal dimension in the Y axis direction. As illustrated in FIG. 3A, a plurality of sense gate trench portions 140 and a plurality of sense dummy trench portions 130 are provided.

The sense gate trench portion 140 has the trench, the sense gate insulating film 142, and the sense gate conductive portion 144. The sense gate insulating film 142 is provided to cover the inner wall of the trench. The sense gate insulating film 142 may be formed by oxidizing or nitriding the semiconductor of the inner wall of the trench. The sense gate conductive portion 144 is provided inward of the sense gate insulating film 142 inside the trench. That is, the sense gate insulating film 142 insulates the sense gate conductive portion 144 and the semiconductor substrate 10. The sense gate conductive portion 144 is formed of a conductive material such as polysilicon.

The sense dummy trench portion 130 has a trench, the sense dummy insulating film 132, and the sense dummy conductive portion 134. The structure of the sense dummy trench portion 130 may be similar to that of the sense gate trench portion 140. However, the sense gate conductive portion 144 is connected to the sense gate runner 148, whereas the sense dummy trench portion 130 does not have to be connected to the sense gate runner 148. The sense dummy conductive portion 134 may be connected to the sense emitter electrode 152 in the cross section different from the B-B' cross section. In the B-B' cross section, the sense gate trench portion 140 and the sense dummy trench portion 130 are covered with the interlayer insulating film 38 on the upper surface 21 of the semiconductor substrate 10.

The sense transistor portion 170 has the mesa portion 160 that is a region between the sense gate trench portions 140 or the sense dummy trench portions 130. In this example, the mesa portion 160 is provided between each trench portions in the X axis direction and extends in the Y axis direction. In the mesa portion 160, the emitter region 12, the base region 14, and the accumulation region 16 are provided from the upper surface 21.

The sense transistor portion 170 has the emitter region 12 of a first conductivity type provided at the upper surface 21. The emitter region 12 is exposed on the upper surface 21 of the semiconductor substrate 10, and is provided in contact with the sense gate trench portion 140 and the sense dummy trench portion 130. The emitter region 12 may be in contact with the trench portions on both sides of the mesa portion 160. The emitter region 12 has a higher doping concentration than the drift region 18. The emitter region 12 of this example is of an N+ type.

The base region 14 is provided below the emitter region 12. The base region 14 in this example is provided in contact with the emitter region 12. The base region 14 may be in contact with the trench portions on both sides of the mesa portion 160. The sense gate conductive portion 144 may be provided longer than the base region 14 in the depth direction. When a predetermined gate voltage is applied to the sense gate conductive portion 144, the channel of an electron inversion layer is formed in a surface layer of the interface, of the base region 14, that is in contact with the sense gate trench portion 140. As a result, in the main transistor portion 70, the current flows between the main emitter electrode 52 and the collector electrode.

The accumulation region 16 is provided below the base region 14. The accumulation region 16 is a region of the N+ type having a higher doping concentration than the drift region 18. In the semiconductor substrate 10 of this example, the accumulation region 16-1 and the accumulation region 16-2 are provided, but the number of accumulation regions 16 is not limited to two. The number, doping concentration, and the like of the accumulation regions 16 may be the same as those of the main transistor portion 70. The same applies to the other regions.

In the mesa portion 160 provided at the outermost end of the sense transistor portion 170 in the X axis direction, the emitter region 12 and the accumulation region 16 do not have to be provided. In the mesa portion 160, the P+ contact region 17 may be provided on the surface side of the base region 14. Also in the region between the trench portion provided at the outermost end of the sense transistor portion 170 in the X axis direction (in this example, the sense gate trench portion 140) and the sense well region 129, the emitter region 12 and the accumulation region 16 do not have to be provided. In the region, the P+ contact region 17 may be provided on the surface side of the base region 14 adjacent to the sense well region 129. For example, the P+ contact region 17 is provided so as to be in contact with the inner periphery of the sense well region 129 and to surround the sense transistor portion 170. The P+ contact region 17 is connected to the sense emitter electrode 152 via the contact hole 54. This can make it easier to extract the holes which have flowed into the sense well region 129.

In a cross section different from the B-B' cross section, the contact region of a second conductivity type may be provided in the sense transistor portion 170. The contact region may be provided between the base region 14 and the upper surface 21. The contact region may be a region of the P+ type having a higher doping concentration than the base region 14. By providing the contact region in the sense transistor portion 170, holes that have migrated around from the main transistor portion 70 can be extracted via the contact region.

The main well region 29 and the sense well region 129 are formed from the upper surface 21 of the semiconductor substrate 10 toward a depth direction. The main well region 29 and the sense well region 129 of this example are P+ type. The main well region 29 and the sense well region 129 may be formed to a depth deeper than the sense gate trench portion 140 and the sense dummy trench portion 130. The sense well region 129 may be connected to the sense emitter electrode 152 via the contact hole 54. The base region 14 and the P+ contact region 17 may be formed between the main well region 29 and the sense well region 129.

The interlayer insulating film 39 is provided on the upper surface 21 above the main well region 29 and the sense well region 129. The interlayer insulating film 39 may be a native oxide film, and may be the sense gate insulating film 142 formed up to the upper surface 21 of the semiconductor substrate 10.

The second polysilicon layer 48-1 and the third polysilicon layer 148-1 are provided above the interlayer insulating film 39. The second metal layer 48-2 is provided above the second polysilicon layer 48-1 via the interlayer insulating film 38. The second polysilicon layer 48-1 and the second metal layer 48-2 are connected via the contact hole 64 formed in the interlayer insulating film 38. Similarly, the third metal layer 148-2 is provided above the third polysilicon layer 148-1 via the interlayer insulating film 38. The third polysilicon layer 148-1 and the third metal layer 148-2 are connected via the contact hole 64 formed in the interlayer insulating film 38.

The gate runner connection portion 50 is provided between the main gate runner 48 and the sense gate runner 148. The gate runner connection portion 50 connects the main gate runner 48 and the sense gate runner 148. The gate runner connection portion 50 has the resistor portion 59. The resistor portion 59 of this example includes polysilicon disposed above the upper surface 21 of the semiconductor substrate 10. In this specification, the polysilicon of the resistor portion 59 is referred to as the first polysilicon layer 61.

The first polysilicon layer 61 is formed above the interlayer insulating film 39. The first polysilicon layer 61 is connected to the second polysilicon layer 48-1. The first polysilicon layer 61 is also connected to the third polysilicon layer 148-1. That is, the first polysilicon layer 61 connects the second polysilicon layer 48-1 and the third polysilicon layer 148-1. The first polysilicon layer 61 of this example is polysilicon provided from the end portion, closest to the gate runner connection portion 50, of contact holes 64 that connect the second polysilicon layer 48-1 and the second metal layer 48-2 to the end portion, closest to the gate runner connection portion 50, of contact holes bthat connect the third polysilicon layer 148-1 and the third metal layer 148-2.

The main gate runner 48 and the sense gate runner 148 have a stacked structure, but the gate runner connection portion 50 of this example receives the gate signal transmitted via the first polysilicon layer 61. Therefore, the resistance value becomes higher than those of the main gate runner 48 and the sense gate runner 148. Therefore, the above-described parallel oscillation can be suppressed, and oscillation of the gate voltage of the sense transistor portion 170 can be suppressed.

The first polysilicon layer 61 may be formed in the same process as the second polysilicon layer 48-1 and the third polysilicon layer 148-1. Thus, the first polysilicon layer 61 can be formed without increasing manufacturing processes. The doping concentration of the first polysilicon layer 61 may be the same as the doping concentration of the second polysilicon layer 48-1 and the doping concentration of the third polysilicon layer 148-1. The thickness of the first polysilicon layer 61 may be the same as the thickness of the second polysilicon layer 48-1 and the thickness of the third polysilicon layer 148-1. The thickness of the first polysilicon layer 61 is, as one example, 0.5 μm or more and 1.0 μm or less.

Above the first polysilicon layer 61, the first insulating film 37 is provided, and the metal layer 51 is provided via the first insulating film 37. In addition, although omitted in FIG. 4, polyimide is provided as the protective film above the sense emitter electrode 152, the metal layer 51, the main gate runner 48, and the sense gate runner 148.

When the metal layer 51 is not formed, the polyimide contacts the first insulating film 37 above the first polysilicon layer 61. When the polyimide is charged in that state, charges are also induced on the upper surface of the first polysilicon layer 61 across the first insulating film 37, and the resistance value of the first polysilicon layer 61 changes. As described later, since the resistance value of the resistor portion 59 affects characteristics of the semiconductor device 100, the resistance value is preferably set to the predetermined value. By providing the metal layer 51, the resistance value of the resistor portion 59 can be stabilized. In addition, atomic diffusion from the polyimide can be prevented.

The metal layer 51 may cover 50% or more of the area of the first polysilicon layer 61, may cover 80% or more thereof, and may cover 100% thereof. However, in a top view, at least a part of the first polysilicon layer 61 does not have to be covered with the metal layer 51. 30% or more of the area of the first polysilicon layer 61 does not have to be covered with the metal layer 51, 50% or more thereof does not have to be covered with the metal layer 51, and 80% or more thereof does not have to be covered with the metal layer 51.

The metal layer 51 of this example is insulated from the first polysilicon layer 61 by the first insulating film 37 in the gate runner connection portion 50. In this specification, when there is an interposed insulating film region in which the first insulating film 37 is provided between the metal layer 51 and the first polysilicon layer 61, even if the metal layer 51 and the first polysilicon layer 61 are connected in another region, the metal layer 51 and the first polysilicon layer 61 are assumed to be insulated from each other in the interposed insulating film region. The region in which the first insulating film 37 is provided between the metal layer 51 and the first polysilicon layer 61 and in which no contact hole is provided in the first insulating film 37 is the interposed insulating film region. A region obtained by extending, in the Y axis direction, the contact hole provided in the first insulating film 37 does not have to be treated as an interposed insulating film region. The interposed insulating film region may refer to, in the metal layer 51, the portion in which no gate current flows and which does not function as a runner.

In another example, the contact hole may be formed in the first insulating film 37, and the metal layer 51 and the first polysilicon layer 61 may be connected. Even in that case, in the X axis direction, the interposed insulating film region in which the metal layer 51 and the first polysilicon layer 61 are insulated from each other may be provided in a range of 50% or more of the length of the gate runner connection portion 50. The interposed insulating film region in this case may be the region from an end portion, closest to the second metal layer 48-2, of the contact holes provided in the first insulating film 37 to an end portion, closest to the second metal layer 48-2, of the metal layer 51.

The metal layer 51 may be connected to either one of the main gate runner 48 or the sense gate runner 148. The metal layer 51 of this example is connected to the third metal layer 148-2 of the sense gate runner 148. The metal layer 51 may be the portion in which the second metal layer 48-2 or the third metal layer 148-2 extends above the gate runner connection portion 50. However, the metal layer 51 does not have to be connected to neither the main gate runner 48 nor the sense gate runner 148. In the example of FIG. 4, the metal layer 51 is provided so as to extend from the third metal layer 148-2 in the direction toward the second metal layer 48-2. The metal layer 51 may be electrically floating without being connected to neither the second metal layer 48-2 nor the third metal layer 148-2.

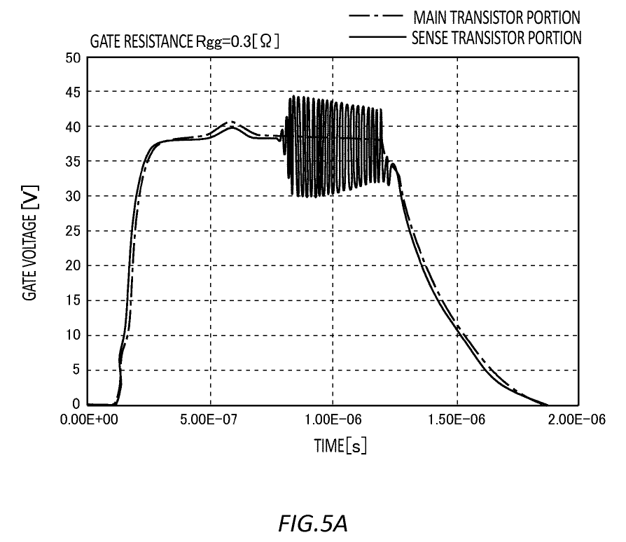

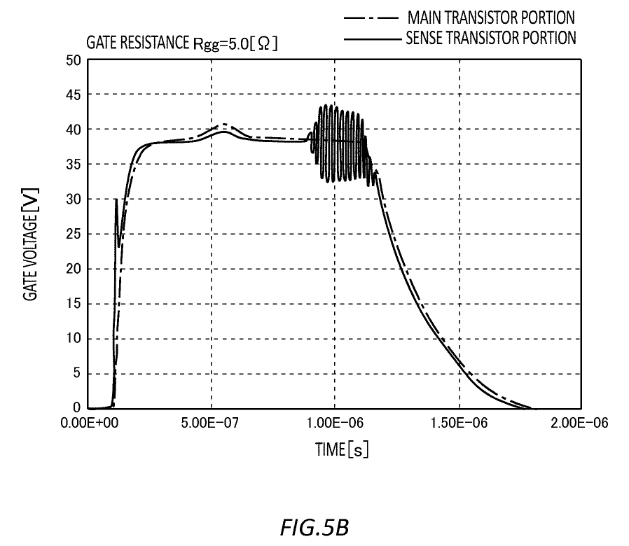

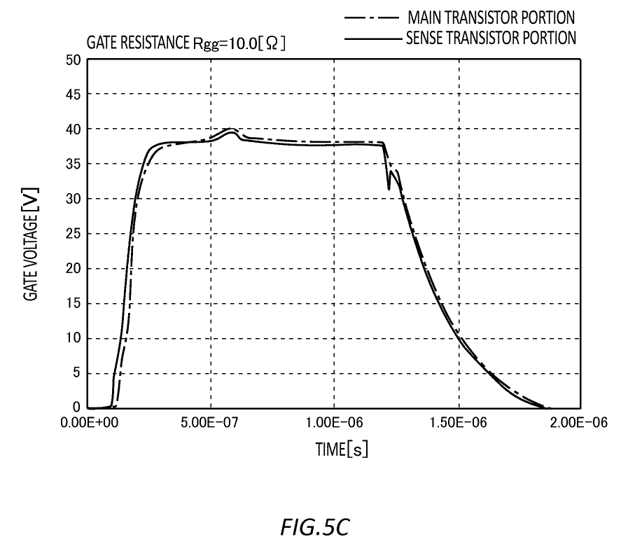

FIGS. 5A, 5B, and 5C are diagrams illustrating simulation results of gate voltage. In FIGS. 5A, 5B, and 5C, changes in the gate voltages of the main transistor portion 70 and the sense transistor portion 170 from turn-on to turn-off of the semiconductor device 100 were simulated. The horizontal axis of each figure indicates time, and the vertical axis indicates voltage.

In FIG. 5A, the simulation result in which the resistance value of the gate runner connection portion 50 is 0.3 Ω is illustrated. This example assumes a case where the gate runner connection portion 50 does not have the resistor portion 59 and the main gate runner 48 or the sense gate runner 148 is used as the gate runner connection portion 50. In this case, oscillation of the gate voltage of the sense transistor portion 170 was confirmed after a certain period had elapsed since the semiconductor device 100 was turned on.

In FIG. 5B, the simulation result in which the resistance value of the gate runner connection portion 50 is 5.0 Ω is illustrated. This example assumes a case where the gate runner connection portion 50 has the resistor portion 59. Also in this case, the oscillation of the gate voltage of the sense transistor portion 170 was confirmed. However, the amplitude of the gate voltage is smaller than that in the case of FIG. 5A. In addition, the time during which the gate voltage is oscillating is shorter than that in the case of FIG. 5A. This is considered to be because the gate runner connection portion 50 has the resistor portion 59.

In FIG. 5C, the simulation result in which the resistance value of the gate runner connection portion 50 is 10.0 Ω is illustrated. This example assumes a case where the resistance value of the gate runner connection portion 50 is further increased. In this case, no oscillation of the gate voltage was confirmed. That is, it was confirmed that oscillation of the gate voltage is suppressed by increasing the resistance value of the gate runner connection portion 50.

However, if the resistance value of the gate runner connection portion 50 is increased too much, the gate signal of the sense transistor portion 170 is delayed relative to the gate signal of the main transistor portion 70. In particular, if the gate signal of the sense transistor portion 170 is delayed at turn-off, the current concentrates on the sense transistor portion 170, and the sense transistor portion 170 may be destroyed. Therefore, it is desirable to adjust the resistance value of the gate runner connection portion 50 to the appropriate value.

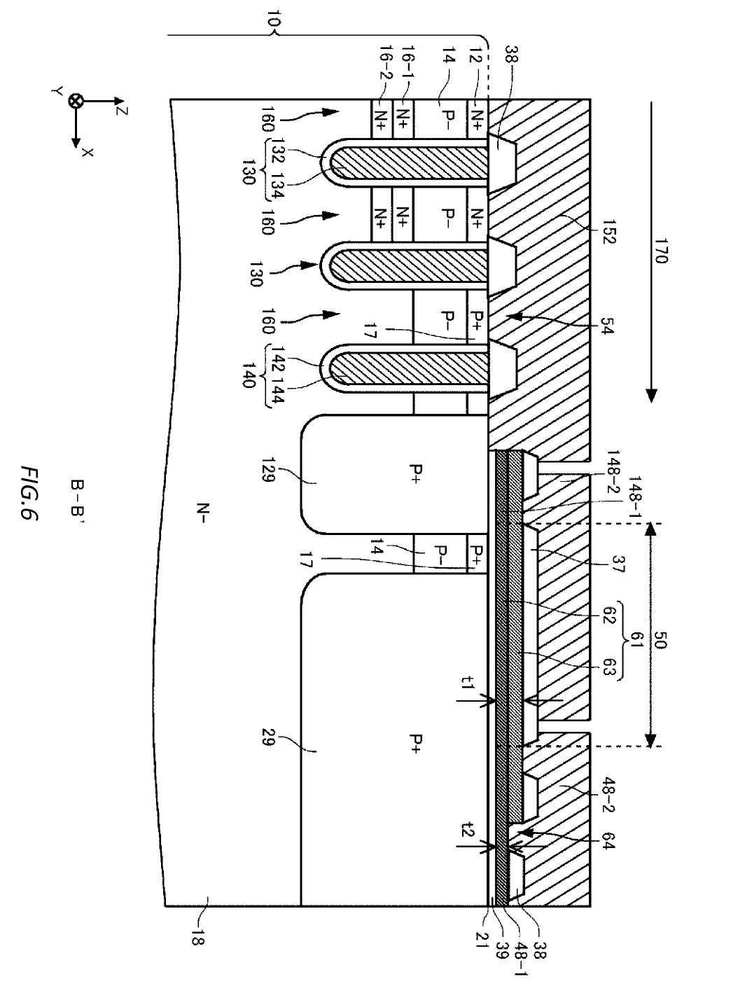

FIG. 6 is a diagram illustrating another example of the B-B' cross section in FIG. 3A. The first polysilicon layer 61 of this example has a thickness different from that of the first polysilicon layer 61 shown in FIG. 4. Other configurations are the same as the configuration shown in FIG. 4, and thus description thereof is omitted.

The first polysilicon layer 61 of this example has a thickness different from that of the second polysilicon layer 48-1. The first polysilicon layer 61 of this example has a stacked structure of an upper polysilicon layer 63 and a lower polysilicon layer 62. The thickness t1 of the first polysilicon layer 61 of this example is greater than the thickness t2 of the second polysilicon layer 48-1. The resistance value of the gate runner connection portion 50 can be adjusted by adjusting the thickness t1 of the first polysilicon layer 61. The thickness t1 may be two times the thickness t2 or more. As the thickness of the polysilicon layer, the average value may be used, or the maximum value may be used.

However, the thickness t1 may be smaller than the thickness t2. In that case, the first polysilicon layer 61 does not have to have the stacked structure of the upper polysilicon layer 63 and the lower polysilicon layer 62. For example, the thickness t1 can be reduced by etching the first polysilicon layer 61. The thickness t1 may be two times the thickness t2 or less.

The upper polysilicon layer 63 of this example covers the entirety of the lower polysilicon layer 62. The upper polysilicon layer 63 may be formed in the same process as the polysilicon of the temperature sense runner 112 described above (see FIG. 2). The lower polysilicon layer 62 may be formed in the same process as the second polysilicon layer 48-1. Thus, the upper polysilicon layer 63 and the lower polysilicon layer 62 can be formed without increasing the number of manufacturing processes.

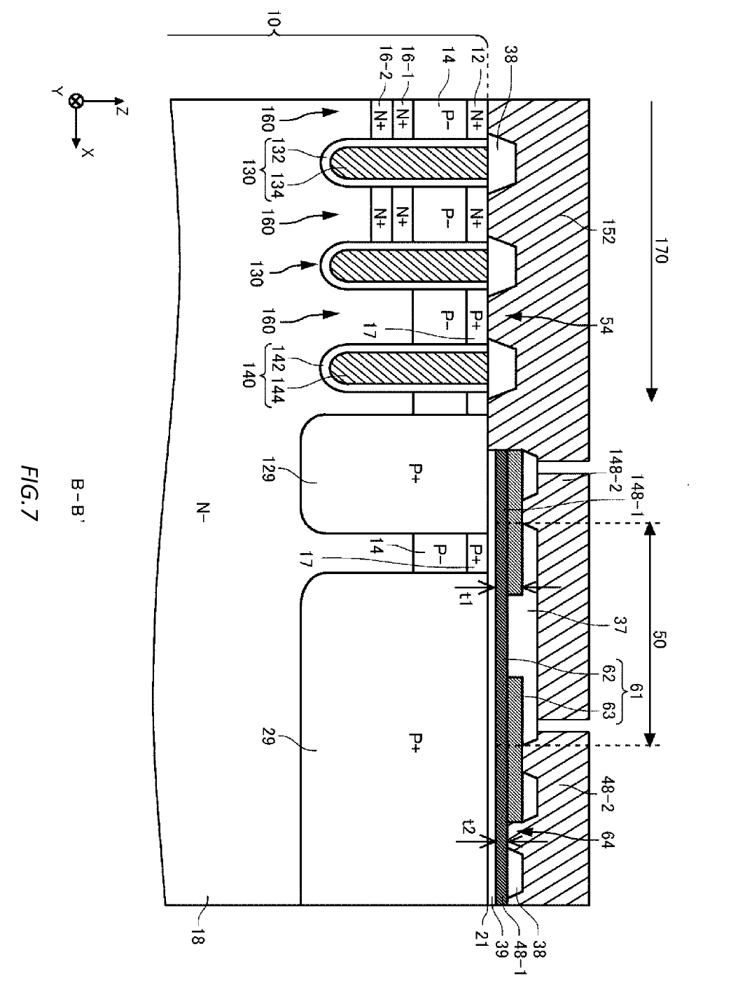

The upper polysilicon layer 63 may have a thickness and a doping concentration equal to those of the temperature sense runner 112. The lower polysilicon layer 62 may have a thickness and a doping concentration equal to those of the second polysilicon layer 48-1. The upper polysilicon layer 63 and the lower polysilicon layer 62 may have different thicknesses, and may have different doping concentrations. The example illustrated in FIG. 6 may be combined with any other modification example other than the modification example illustrated in FIG. 7.

FIG. 7 is a diagram illustrating another example of the B-B' cross section in FIG. 3A. The first polysilicon layer 61 of this example also has a stacked structure of the upper polysilicon layer 63 and the lower polysilicon layer 62 similarly to FIG. 6. However, the upper polysilicon layer 63 of this example is not provided on part of the upper surface of the lower polysilicon layer 62. The upper polysilicon layer 63 of this example can be formed by partially etching the upper polysilicon layer 63. The etching may be performed in the same process as the etching of the temperature sense runner 112. Such a configuration can also adjust the resistance value of the gate runner connection portion 50. The upper polysilicon layer 63 may be provided in a range of 20% or more and 40% or less, 40% or more and 60% or less, or 60% or more and 80% or less of the upper surface of the lower polysilicon layer 62. The example illustrated in FIG. 7 may be combined with any other modification example other than the modification example illustrated in FIG. 6.

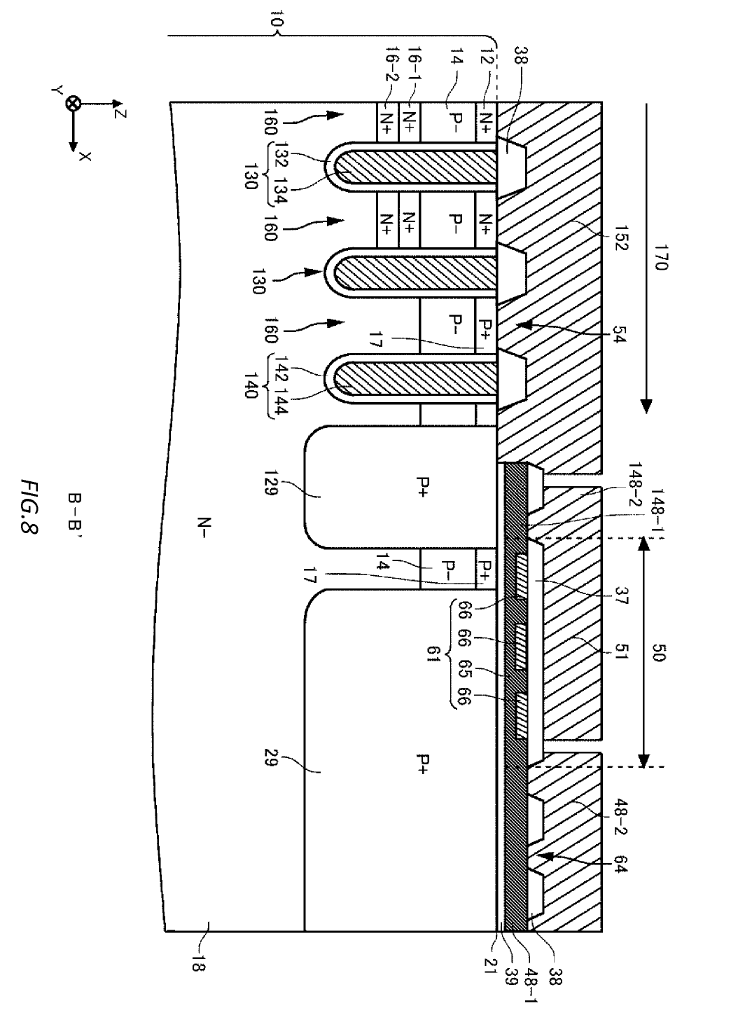

FIG. 8 is a diagram illustrating another example of the B-B' cross section in FIG. 3A. In the first polysilicon layer 61 of this example, regions having different doping concentrations are formed. Other configurations are the same as the configuration shown in FIG. 4, and thus description thereof is omitted.

The first polysilicon layer 61 of this example has the high-concentration region 66 having a dopant at a predetermined concentration and the low-concentration region 65 having a dopant concentration lower than that of the high-concentration region 66. The first conductivity type dopant may be implanted into the high-concentration region 66. The low-concentration region 65 may be the region remaining without being implanted with a dopant. Such a configuration can also adjust the resistance value of the gate runner connection portion 50. The example illustrated in FIG. 8 may be combined with any other modification example.

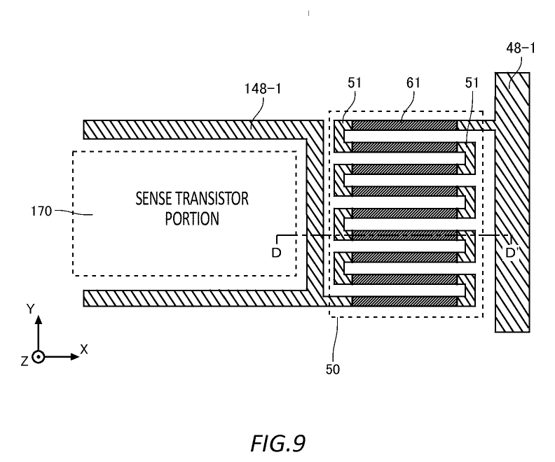

FIG. 9 is a diagram illustrating one example of the configuration of the gate runner connection portion 50 in a top view. FIG. 9 illustrates positions of the gate runner connection portion 50, the second polysilicon layer 48-1, the third polysilicon layer 148-1, and the sense transistor portion 170 in a top view.

The gate runner connection portion 50 of this example also has the first polysilicon layer 61 and the metal layer 51. However, the gate runner connection portion 50 of this example has a bellows-like structure folded back a plurality of times from the connection point with the second polysilicon layer 48-1 to the connection point with the third polysilicon layer 148-1. Such a configuration can also adjust the resistance value of the gate runner connection portion 50.

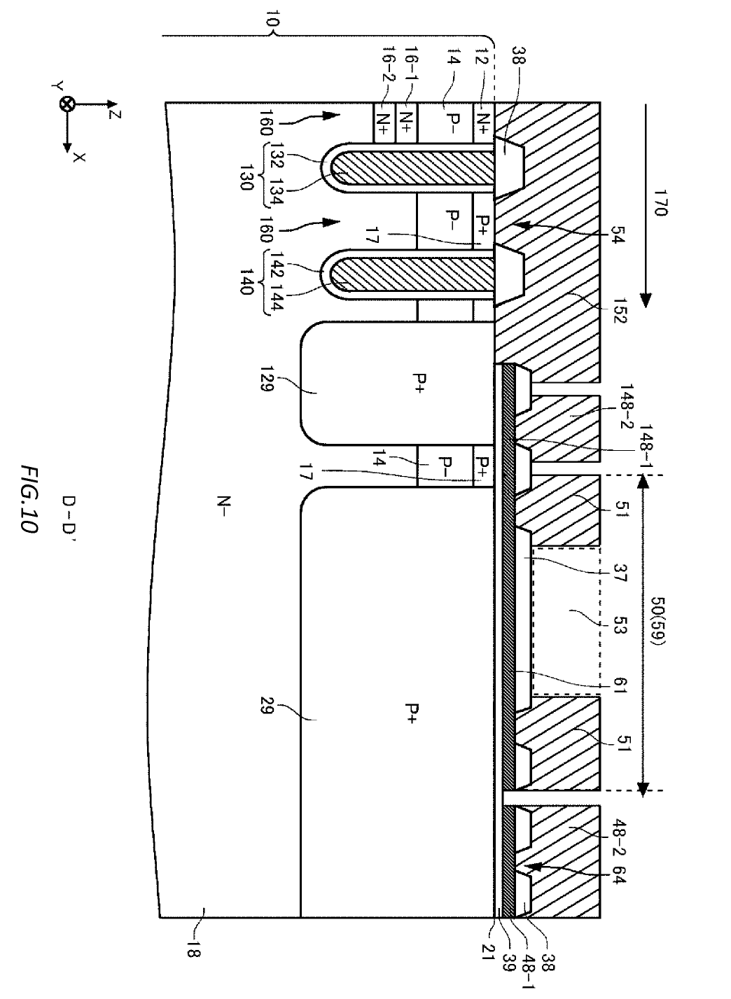

FIG. 10 is a diagram illustrating one example of the D-D’ cross section in FIG. 9. In the D-D' cross section, the gate runner connection portion 50 has the first polysilicon layer 61 and the metal layer 51. The metal layer 51 of this example is connected to the first polysilicon layer 61 via the contact hole provided in the first insulating film 37. The metal layer 51 corresponds to a crest portion or a trough portion of the bellows, and the first polysilicon layer 61 is connected, via the metal layer 51, to the first polysilicon layer 61 in another cross section.

In the gate runner connection portion 50, a region above the first insulating film 37 is defined as the adjustment portion 53. In the D-D' cross section, one of the two metal layers 51 may extend to the adjustment portion 53 and may be connected to the other metal layer 51. In that case, the resistance value of the gate runner connection portion 50 in the D-D' cross section becomes low, and the overall resistance value of the gate runner connection portion 50 also becomes low. Also, a portion of the metal layer 51 may be formed of polysilicon. Such a configuration can also adjust the resistance value of the gate runner connection portion 50.

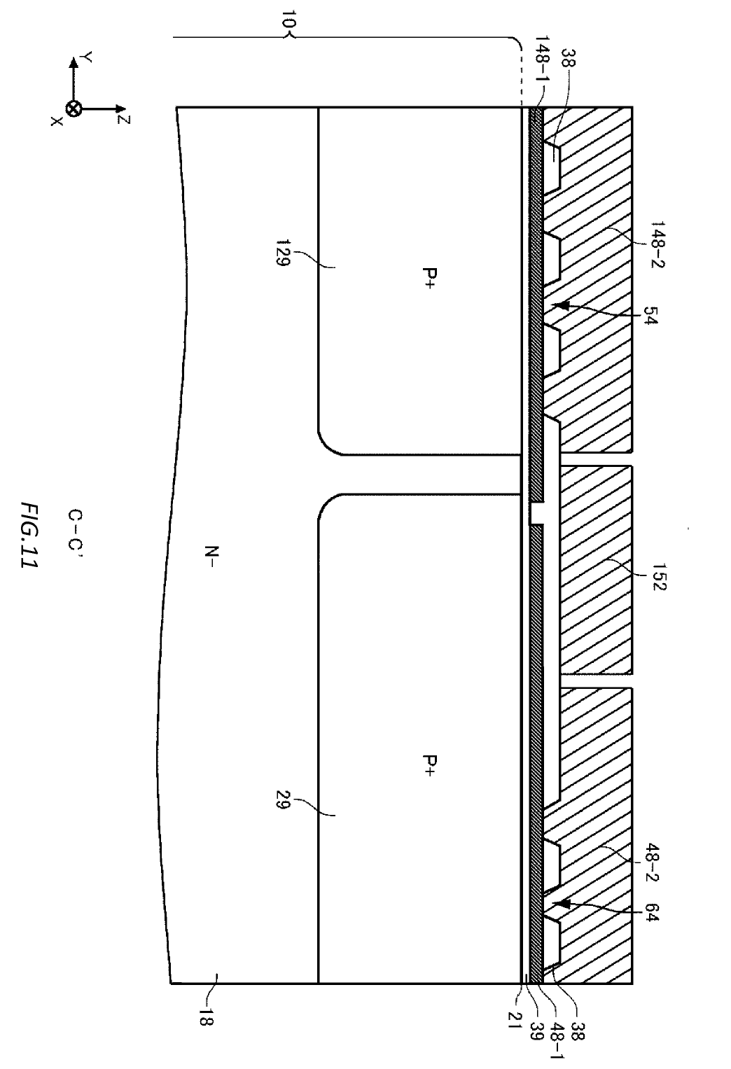

FIG. 11 is a diagram illustrating one example of the C-C' cross section of FIG. 3A. The C-C' cross section is the cross section that crosses, in the Y axis direction, from the sense gate runner 148 to the main gate runner 48. In the C-C' cross section, the semiconductor substrate 10 is provided with the sense well region 129 and the main well region 29.

Above the upper surface 21 of the semiconductor substrate 10, the second polysilicon layer 48-1 and the third polysilicon layer 148-1 are provided via the interlayer insulating film 39. Above the second polysilicon layer 48-1, the second metal layer 48-2 is provided via the interlayer insulating film 38, and the second polysilicon layer 48-1 and the second metal layer 48-2 are connected via the contact hole 64 of the interlayer insulating film 38. The same is true for the third polysilicon layer 148-1 and the third metal layer 148-2 are similarly configured.

The sense emitter electrode 152 extends between the second metal layer 48-2 and the third metal layer 148-2. In the C-C' cross section, the sense emitter electrode 152 and the second polysilicon layer 48-1 and the third polysilicon layer 148-1 are insulated by the interlayer insulating film 38.

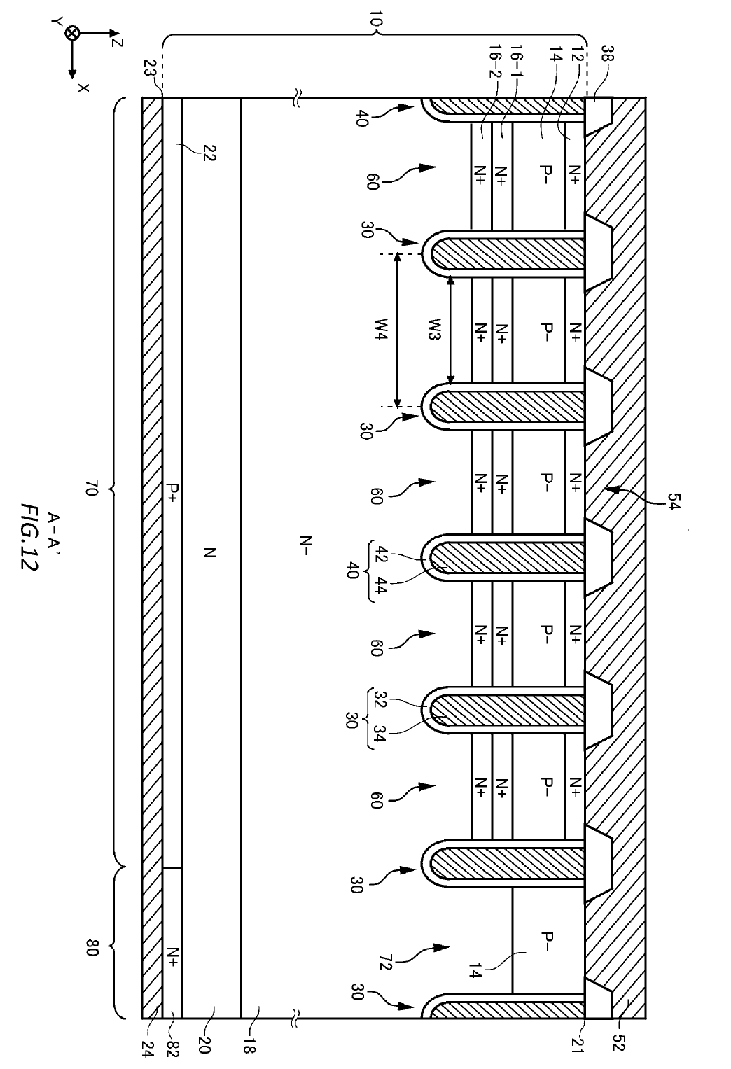

FIG. 12 is a diagram illustrating one example of a cross section A-A’ in FIG. 2. The A-A' cross section is the XZ cross section passing through the emitter region 12 of the main transistor portion 70 and the diode portion 80. In the A-A' cross section, the semiconductor device 100 includes the semiconductor substrate 10, the collector electrode 24, the interlayer insulating film 38, and the main emitter electrode 52. The semiconductor substrate 10 has an upper surface 21 and a lower surface 23. The upper surface 21 and the lower surface 23 are two main surfaces of the semiconductor substrate 10. Hereinafter, for the configuration similar to the sense transistor portion 170 described in FIG. 4 and the like, description will be omitted as appropriate.

The interlayer insulating film 38 is provided on the upper surface 21 of the semiconductor substrate 10. The main emitter electrode 52 is provided above the interlayer insulating film 38. The main emitter electrode 52 is in contact with an upper surface 21 of the semiconductor substrate 10 through the contact hole 54 of the interlayer insulating film 38. The collector electrode 24 is provided on a lower surface 23 of the semiconductor substrate 10. The main emitter electrode 52 and the collector electrode 24 are formed of a metal material such as aluminum.

The main transistor portion 70 and the diode portion 80 have the drift region 18 of a first conductivity type, and the base region 14 of a second conductivity type provided between the drift region 18 and the upper surface 21 of the semiconductor substrate 10. The drift region 18 of this example is of an N- type, and the base region 14 is of a P- type.

In the main transistor portion 70, a plurality of main gate trench portions 40 and a plurality of main dummy trench portions 30 are provided from the upper surface 21 of the semiconductor substrate 10 toward the inside. The main gate trench portions 40 and the main dummy trench portions 30 of this example are arranged along the X axis direction and have a longitudinal dimension in the Y axis direction. The main gate trench portion 40 includes a trench, the main gate insulating film 42, and the main gate conductive portion 44. The main gate insulating film 42 is provided to cover the inner wall of the trench. The main gate insulating film 42 may be formed by oxidizing or nitriding the semiconductor of the inner wall of the trench. The main gate conductive portion 44 is provided inward of the main gate insulating film 42 inside the trench. That is, the main gate insulating film 42 insulates the main gate conductive portion 44 and the semiconductor substrate 10. The main gate conductive portion 44 is formed of a conductive material such as polysilicon.

The main dummy trench portion 30 includes the trench, the main dummy insulating film 32, and the main dummy conductive portion 34. The structure of the main dummy trench portion 30 may be similar to that of the main gate trench portion 40. However, the main gate conductive portion 44 is connected to the main gate runner 48, whereas the main dummy trench portion 30 does not have to be connected to the main gate runner 48. The main dummy conductive portion 34 may be connected to the main emitter electrode 52 in a cross section different from the A-A’ cross section. The diode portion 80 also includes the plurality of main dummy trench portions 30.

The main transistor portion 70 includes the mesa portion 60 that is a region between the main gate trench portions 40 or the main dummy trench portions 30. Similarly, the diode portion 80 includes the mesa portion 72 that is a region between the main dummy trench portions 30. Each mesa portion is provided with the base region 14.

The main transistor portion 70 has the emitter region 12 of the first conductivity type provided at the upper surface 21. The emitter region 12 is exposed on the upper surface 21 of the semiconductor substrate 10, and is provided in contact with the main gate trench portion 40 or the main dummy trench portion 30. The emitter region 12 may be in contact with the main gate trench portion 40 or the main dummy trench portion 30 on both sides of the mesa portion 60.

The base region 14 is provided below the emitter region 12. The base region 14 in this example is provided in contact with the emitter region 12. The base region 14 may be in contact with the main gate trench portion 40 or the main dummy trench portion 30 on both sides of the mesa portion 60.

The accumulation region 16 is provided below the base region 14. The accumulation region 16 is a region of the N+ type having a higher doping concentration than the drift region 18. Providing the accumulation region 16 having a high concentration between the drift region 18 and the base region 14 can increase a carrier implantation enhancement effect (IE effect) and reduce an on-voltage. The accumulation region 16 may be provided so as to cover the entire lower surface of the base region 14 in each mesa portion 60.

The mesa portion 72 of the diode portion 80 is provided with the P- type of base region 14 in contact with the upper surface 21 of the semiconductor substrate 10. The drift region 18 is provided below the base region 14. The mesa portion 72 of the diode portion 80 is not provided with the emitter region 12.

The main transistor portion 70 has the collector region 22 of the second conductivity type provided at the lower surface 23 of the semiconductor substrate 10. The collector region 22 in this example is of the P+ type. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

The diode portion 80 includes a cathode region 82 of the first conductivity type provided on the lower surface 23 of the semiconductor substrate 10. The cathode region 82 in this example is of N+ type. A donor concentration of the cathode region 82 is higher than a donor concentration of the drift region 18. A donor of the cathode region 82 is, for example, hydrogen or phosphorous. Note that an element serving as a donor and an acceptor in each region is not limited to the example described above.

The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10.

The main transistor portion 70 may be a region in which the collector region 22 is provided on the lower surface 23. The diode portion 80 may be the region in which the cathode region 82 is provided on the lower surface 23. A boundary between the main transistor portion 70 and the diode portion 80 may be the boundary between the cathode region 82 and the collector region 22.

A buffer region 20 of the N type may be provided between the drift region 18, and the collector region 22 and the cathode region 82. The doping concentration in the buffer region 20 is higher than the doping concentration in the drift region 18. The buffer region 20 may function as a field stopper layer which prevents a depletion layer expanding from a lower end of the base region 14 from reaching a collector region 22 of the P+ type.

In the cross section different from the A-A’ cross section, a contact region of the second conductivity type may be provided on the main transistor portion 70 and the diode portion 80. The contact region may be provided between the base region 14 and the upper surface 21. The contact region may be a region of the P+ type having a higher doping concentration than the base region 14.

The main gate trench portion 40 and the main dummy trench portion 30 extend from the upper surface 21 of the semiconductor substrate 10, pass through the base region 14, and reach the drift region 18. In the region in which at least any of the emitter region 12, the contact region, or the accumulation region 16 is provided, the main gate trench portion 40 and the main dummy trench portion 30 also pass through these doping regions and reach the drift region 18. The configuration of the trench portion penetrating the doping region is not limited to the one manufactured in the order of forming the doping region and then forming the trench portion. The configuration of the trench portions penetrating the doping region also includes a configuration of forming the trench portions and then forming the doping region between the trench portions. It should be noted that a bottom portion of the gate trench portion may have a curved-surface shape (a curved-line shape in the cross section) protruding downward.

The main gate conductive portion 44 may be provided longer than the base region 14 in the depth direction. The main gate trench portion 40 is covered with the interlayer insulating film 38 on the upper surface 21 of the semiconductor substrate 10. The main gate conductive portion 44 is electrically connected to the main gate runner 48. When a predetermined gate voltage is applied to the main gate conductive portion 44, the channel of the electron inversion layer is formed in a surface layer of the interface, of the base region 14, that is in contact with the main gate trench portion 40. In this way, in the main transistor portion 70, the main current flows between the main emitter electrode 52 and the collector electrode 24.

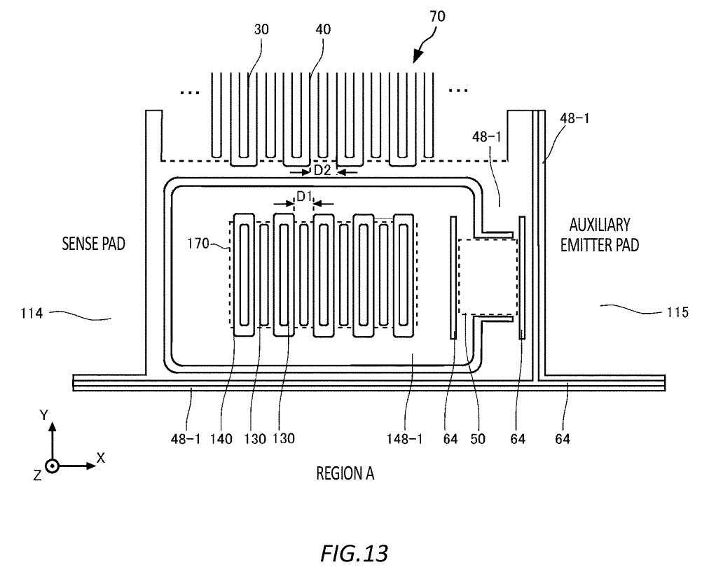

FIG. 13 is a diagram illustrating another example of the region A in FIG. 2. FIG. 13 illustrates the arrangement of the main gate trench portion 40 and the main dummy trench portion 30 of the main transistor portion 70, and the arrangement of the sense gate trench portion 140 and the sense dummy trench portion 130 of the sense transistor portion 170.

The main gate trench portion 40, the main dummy trench portion 30, the sense gate trench portion 140, and the sense dummy trench portions 130 are each provided in plurality. Each trench portion may extend in the same direction. Each trench portion of this example extends in the Y axis direction and is arranged in the X axis direction. In addition, in FIG. 13, hatching is not applied to the second polysilicon layer 48-1 and the third polysilicon layer 148-1. Furthermore, the contact holes 64 on the positive side and the negative side in the Y axis direction of the sense transistor portion 170 are omitted.

In a top view, the density occupied by the sense gate trench portion 140 may be greater than the density occupied by the main gate trench portion 40. The density is the number of the trench portions per unit area. At that time, even if end portions of straight portions of each trench portions are connected, the number of straight portions may be counted. As a result, since the gate-emitter capacitance of the sense transistor portion 170 increases, oscillation of the gate voltage of the sense transistor portion 170 can be suppressed.

The distance D1 between the plurality of sense gate trench portions 140 may be smaller than the distance D2 between the plurality of main gate trench portions 40. As a result, the density of the sense gate trench portions 140 increases and the gate-emitter capacitance of the sense transistor portion 170 increases, so that oscillation of the gate voltage can be suppressed. The sense dummy trench portion 130 may be provided between the plurality of sense gate trench portions 140, and the main dummy trench portion 30 may be provided between the plurality of main gate trench portions 40. The distance D1 may be equal to or less than half of the distance D2. The example illustrated in FIG. 13 may be combined with any other modification example.

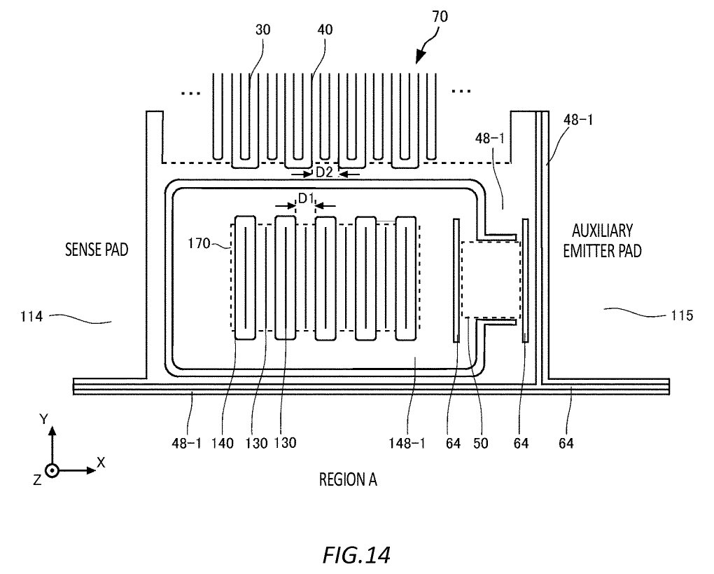

FIG. 14 is a diagram illustrating another example of the region A in FIG. 2. In FIG. 14, the arrangement of the sense gate trench portions 140 and the sense dummy trench portions 130 of the sense transistor portion 170 is different from the example illustrated in FIG. 13.

The ratio R1 of the number of the sense gate trench portions 140 to the number of the sense dummy trench portions 130 in the sense transistor portion 170 may be greater than the ratio R2 of the number of the main gate trench portions 40 to the number of the main dummy trench portions 30 in the main transistor portion 70. While the ratio R1 of this example is 1, the ratio R2 is 0.5. This also increases the density of the sense gate trench portions 140 and increases the gate-emitter capacitance of the sense transistor portion 170, and thus can suppress oscillation of the gate voltage. The ratio R1 may be two times or more, three times or more, or four times or more of the ratio R2. The example illustrated in FIG. 14 may be combined with any other modification example.

In any example, the semiconductor device 100 may have the short-circuit current density of 5000 A/cm² or more when a rated voltage is applied. Also, the width W1 (see FIG. 4) of the mesa portion 160 of the sense transistor portion 170 and the width W3 (see FIG. 12) of the mesa portion 60 of the main transistor portion 70 may be 1 μm or less. Also, the cell pitch W2 (see FIG. 4) of the sense transistor portion 170 and the cell pitch W4 (see FIG. 12) of the main transistor portion 70 may be 1 μm or more and 3 μm or less. As performance of the semiconductor device 100 improves, oscillation of the gate voltage is more likely to occur, and thus it is desirable to suppress the oscillation.

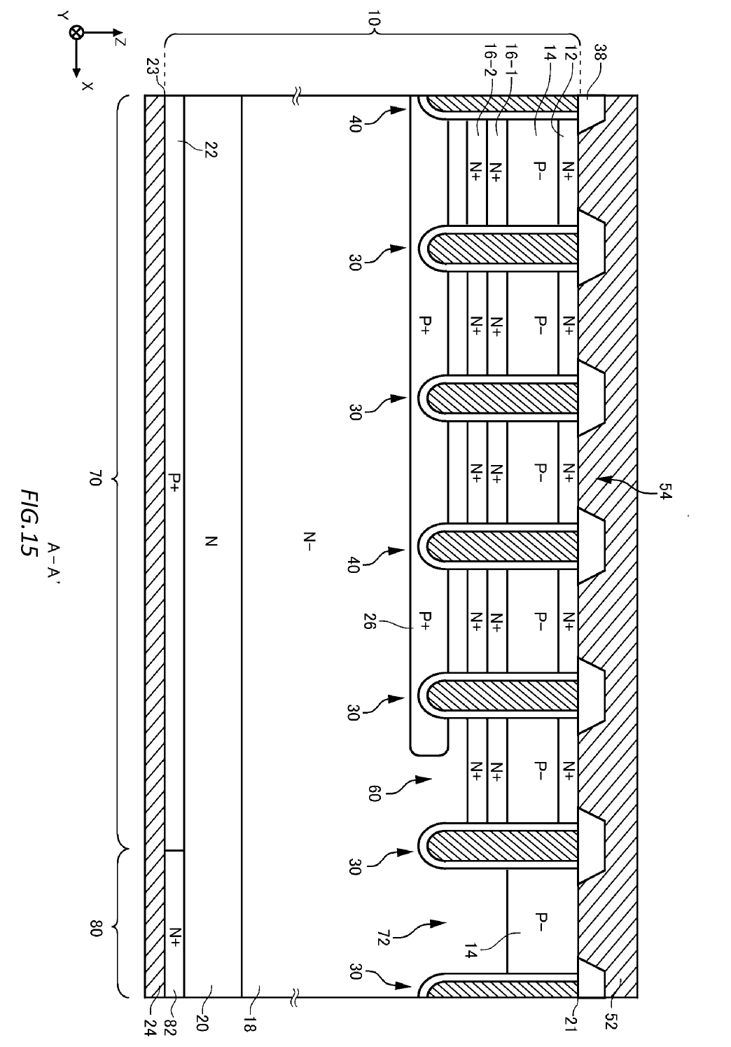

FIG. 15 is a diagram illustrating another example of the cross section A-A’ in FIG. 2. The trench bottom region 26 of the second conductivity type is provided at the bottom portion of the main gate trench portion 40 of this example. The trench bottom region 26 of this example is the P+ type. By providing the trench bottom region 26, it is possible to reduce on-loss. The drift region 18 may exist between the trench bottom region 26 and the base region 14 or the accumulation region 16. The trench bottom region 26 may be provided at the bottom portion of the main dummy trench portion 30, and may be provided across bottom portions of the plurality of trench portions.

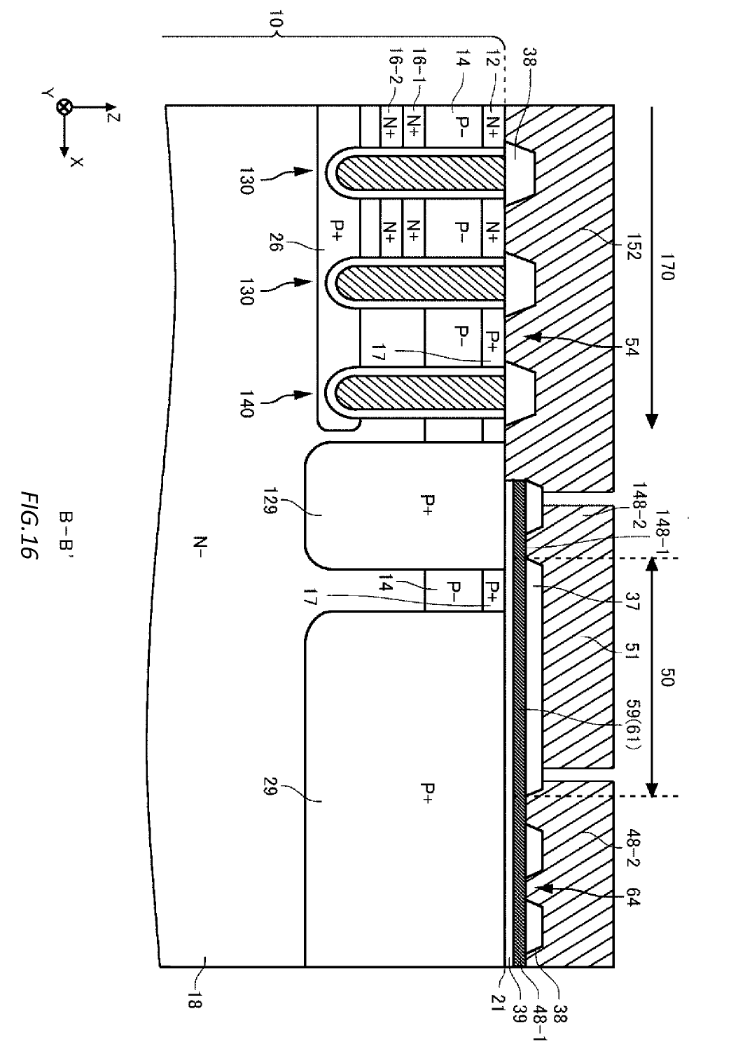

FIG. 16 is a diagram illustrating another example of the B-B’ cross section in FIG. 3A. The trench bottom region 26 of the second conductivity type is provided at the bottom portion of the sense gate trench portion 140 of this example. From a viewpoint of current detection, it is desirable that the configuration of the main transistor portion 70 and the configuration of the sense transistor portion 170 be the same. Therefore, when the trench bottom region 26 is provided in the main transistor portion 70, it is desirable to provide the trench bottom region 26 also in the sense transistor portion 170. However, in that case, voltage dependence of the gate-emitter capacitance of the sense transistor portion 170 changes, and oscillation is more likely to occur. Therefore, it is desirable to suppress oscillation by using the above-described configuration.

The drift region 18 may exist between the trench bottom region 26 and the base region 14 or the accumulation region 16. The trench bottom region 26 may be provided at a bottom portion of the sense dummy trench portion 130, and may be provided across bottom portions of a plurality of trench portions. The trench bottom region 26 of the sense transistor portion 170 and the trench bottom region 26 of the main transistor portion 70 may have the same doping concentration, and may be formed in the same process. However, the trench bottom region 26 may be provided in only one of the main transistor portion 70 or the sense transistor portion 170.

While the present invention has been described by way of the embodiments, the technical scope of the present invention is not limited to the above-described embodiments. It is apparent to persons skilled in the art that various alterations or improvements can be added to the above-described embodiments. It is also apparent from the described scope of the claims that the embodiments added with such alterations or improvements can be included the technical scope of the present invention.

What is claimed is:

1. A semiconductor device comprising a semiconductor substrate having an upper surface, wherein the semiconductor substrate has:
a main transistor portion having a main gate trench portion including a main gate conductive portion;
a sense transistor portion having a sense gate trench portion including a sense gate conductive portion;
a gate pad provided above the upper surface of the semiconductor substrate;
a main gate runner provided above the upper surface of the semiconductor substrate and extending from the gate pad to the main gate conductive portion;
a sense gate runner disposed along the sense transistor portion; and
a gate runner connection portion connecting the main gate runner and the sense gate runner, and
a resistor portion is provided in the gate runner connection portion.

2. The semiconductor device according to claim 1, wherein the semiconductor substrate further has a sense pad disposed adjacent to the sense transistor portion, and
the gate runner connection portion is provided on a side opposite to the sense pad with respect to the sense transistor portion.

3. The semiconductor device according to claim 1, wherein the sense gate trench portion extends in an extending direction, and
the gate runner connection portion is provided at a position overlapping the sense transistor portion in a direction perpendicular to the extending direction in a top view.

4. The semiconductor device according to claim 1, wherein the resistor portion includes a first polysilicon layer disposed above the upper surface of the semiconductor substrate.

5. The semiconductor device according to claim 4, wherein the main gate runner includes a second polysilicon layer disposed above the upper surface of the semiconductor substrate, and
the first polysilicon layer is connected to the second polysilicon layer.

6. The semiconductor device according to claim 4, wherein a metal layer is provided above the first polysilicon layer via an insulating film.

7. The semiconductor device according to claim 6, wherein, in a top view, at least a part of the first polysilicon layer is not covered with the metal layer.

8. The semiconductor device according to claim 4, wherein the main gate runner includes a second polysilicon layer disposed above the upper surface of the semiconductor substrate, and
the first polysilicon layer has a thickness different from a thickness of the second polysilicon layer.

9. The semiconductor device according to claim 8, wherein the first polysilicon layer has a stacked structure of an upper polysilicon layer and a lower polysilicon layer, and
a thickness of the first polysilicon layer is greater than a thickness of the second polysilicon layer.

10. The semiconductor device according to claim 9, wherein the upper polysilicon layer is not provided on a part of an upper surface of the lower polysilicon layer.

11. The semiconductor device according to claim 1, wherein, in a top view, a density occupied by the sense gate trench portion is greater than a density occupied by the main gate trench portion.

12. The semiconductor device according to claim 11, wherein a plurality of main gate trench portions and a plurality of sense gate trench portions are provided, and
a distance between the plurality of sense gate trench portions is smaller than a distance between the plurality of main gate trench portions.

13. The semiconductor device according to claim 11, wherein a plurality of main gate trench portions are provided,
the main transistor portion has a plurality of main dummy trench portions,
a plurality of sense gate trench portions are provided,
the sense transistor portion has a plurality of sense dummy trench portions, and
a ratio of a number of the sense gate trench portions to a number of the sense dummy trench portions in the sense transistor portion is greater than a ratio of a number of the main gate trench portions to a number of the main dummy trench portions in the main transistor portion.

14. The semiconductor device according to claim 1, wherein a short-circuit current density is 5000 A/cm² or more when a rated voltage is applied.

15. The semiconductor device according to claim 1, wherein the sense gate runner is disposed in a closed-loop shape surrounding the sense transistor portion.

16. The semiconductor device according to claim 1, wherein a drift region of a first conductivity type is provided in the semiconductor substrate, and
a trench bottom region of a second conductivity type is provided at a bottom portion of the sense gate trench portion.

17. The semiconductor device according to claim 16, wherein the trench bottom region of the second conductivity type is provided at a bottom portion of the main gate trench portion.

18. A semiconductor device comprising a semiconductor substrate having an upper surface, wherein the semiconductor substrate has:
a drift region of a first conductivity type;
a main transistor portion having a main gate trench portion including a main gate conductive portion;
a sense transistor portion having a sense gate trench portion including a sense gate conductive portion;
a gate pad provided above the upper surface of the semiconductor substrate;
a main gate runner provided above the upper surface of the semiconductor substrate and extending from the gate pad to the main gate conductive portion; and
a gate runner connection portion connecting the main gate runner and the sense gate conductive portion, and
a resistor portion is provided in the gate runner connection portion, and
a trench bottom region of a second conductivity type is provided at a bottom portion of the sense gate trench portion.

19. The semiconductor device according to claim 18, wherein the trench bottom region of the second conductivity type is provided at a bottom portion of the main gate trench portion.

20. The semiconductor device according to claim 18, further comprising a sense gate runner disposed along the sense transistor portion and connected to the sense gate conductive portion,
wherein the gate runner connection portion connects the main gate runner and the sense gate runner.
